(19) United States
(12) Patent Application Publication
(10) Pub. No.: US 2024/0422889 A1
(43) Pub. Date: Dec. 19, 2024

(54) EXTREME ULTRAVIOLET LIGHT GENERATION CHAMBER DEVICE AND ELECTRONIC DEVICE MANUFACTURING METHOD

(71) Applicants: Gigaphoton Inc., Tochigi (JP); Hiroshima University, Hiroshima (JP)

(72) Inventors: Takayuki SUZUKI, Oyama-shi (JP); Atsushi UEDA, Oyama-shi (JP); Georg SOUMAGNE, Oyama-shi (JP); Shinichi NAMBA, Higashihiroshima (JP)

(73) Assignees: Gigaphoton Inc., Tochigi (JP); Hiroshima University, Hiroshima (JP)

(21) Appl. No.: 18/654,475

(22) Filed: May 3, 2024

(30) Foreign Application Priority Data
Jun. 15, 2023 (JP) 2023-098729

(51) Int. Cl. H05G 2/00; G03F 7/00

(52) U.S. Cl. CPC H05G 2/008; G03F 7/70033

(57) ABSTRACT

An extreme ultraviolet light generation chamber device includes a chamber including a plasma generation region in which a droplet target irradiated with laser light is turned into plasma and extreme ultraviolet light is generated, a light concentrating mirror arranged in the chamber and concentrating the extreme ultraviolet light, a gas curtain forming device injecting a gas to form a gas curtain intersecting an optical path of the extreme ultraviolet light propagating from the plasma generation region to the light concentrating mirror, an etching gas supply unit supplying an etching gas into the chamber, and a gas exhaust unit exhausting a residual gas in the chamber. Pressure in a second space that is a space on a side toward the light concentrating mirror from the gas curtain is lower than pressure in a first space that is a space on a side toward the plasma generation region from the gas curtain.

### CROSS-REFERENCE TO RELATED APPLICATIONS

The present application claims the benefit of Japanese Patent Application No. 2023/098729, filed on Jun. 15, 2023 the entire contents of which are hereby incorporated by reference.

### BACKGROUND

### 1. Technical Field

The present disclosure relates to an extreme and an ultraviolet light generation chamber device electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, it is expected to develop a semiconductor exposure apparatus that combines an apparatus for generating extreme ultraviolet (EUV) light having a wavelength of about 13 nm with a reduced projection reflection optical system.

As the EUV light generation apparatus, a laser produced plasma (LPP) type apparatus using plasma generated by irradiating a target substance with laser light has been developed.

### LIST OF DOCUMENTS

### Patent Documents

Patent Document 1: European Patent No. 2211594
Patent Document 2: Japanese Patent Application Publication No. 2005-353294
Patent Document 3: Japanese Patent No. 5108367

### SUMMARY

An extreme ultraviolet light generation chamber device according to an aspect of the present disclosure includes a chamber including, at an internal space thereof, a plasma generation region in which a droplet target irradiated with laser light is turned into plasma and extreme ultraviolet light is generated; a light concentrating mirror arranged in the chamber and configured to concentrate the extreme ultraviolet light; a gas curtain forming device configured to inject a gas at supersonic velocity and form a gas curtain that intersects an optical path of the extreme ultraviolet light propagating from the plasma generation region to the light concentrating mirror; an etching gas supply unit configured to supply an etching gas into the chamber; and a gas exhaust unit configured to exhaust a residual gas in the chamber. In the chamber, pressure in a second space that is a space on a side toward the light concentrating mirror from the gas curtain is lower than pressure in a first space that is a space on a side toward the plasma generation region from the gas curtain and that includes the plasma generation region.

An electronic device manufacturing method according to an aspect of the present disclosure includes outputting extreme ultraviolet light generated using an extreme ultraviolet light generation apparatus including an extreme ultraviolet light generation chamber device to an exposure apparatus, and exposing a photosensitive substrate to the extreme ultraviolet light in the exposure apparatus to manufacture an electronic device. Here, the extreme ultraviolet light generation chamber device includes a chamber including, at an internal space thereof, a plasma generation region in which a droplet target irradiated with laser light is turned into plasma and the extreme ultraviolet light is generated; a light concentrating mirror arranged in the chamber and configured to concentrate the extreme ultraviolet light; a gas curtain forming device configured to inject a gas at supersonic velocity and form a gas curtain that intersects an optical path of the extreme ultraviolet light propagating from the plasma generation region to the light concentrating mirror; an etching gas supply unit configured to supply an etching gas into the chamber; and a gas exhaust device configured to exhaust a residual gas in the chamber. In the chamber, pressure in a second space that is a space on a side toward the light concentrating mirror from the gas curtain is lower than pressure in a first space that is a space on a side to the plasma generation region from the gas curtain and that includes the plasma generation region.

An electronic device manufacturing method according to an aspect of the present disclosure includes inspecting a defect of a mask by irradiating the mask with extreme ultraviolet light generated using an extreme ultraviolet light generation apparatus including an extreme ultraviolet light generation chamber device, selecting a mask using a result of the inspection, and exposing and transferring a pattern formed on the selected mask onto a photosensitive substrate. Here, the extreme ultraviolet light generation chamber device includes a chamber including, at an internal space thereof, a plasma generation region in which a droplet target irradiated with laser light is turned into plasma and the extreme ultraviolet light is generated; a light concentrating mirror arranged in the chamber and configured to concentrate the extreme ultraviolet light; a gas curtain forming device configured to inject a gas at supersonic velocity and form a gas curtain that intersects an optical path of the extreme ultraviolet light propagating from the plasma generation region to the light concentrating mirror; an etching gas supply unit configured to supply an etching gas into the chamber; and a gas exhaust device configured to exhaust a residual gas in the chamber. In the chamber, pressure in a second space that is a space on a side toward the light concentrating mirror from the gas curtain is lower than pressure in a first space that is a space on a side toward the plasma generation region from the gas curtain and that includes the plasma generation region.

### BRIEF DESCRIPTION OF THE DRAWINGS

Embodiments of the present disclosure will be described below merely as examples with reference to the accompanying drawings.

FIG. 1 is a schematic view showing a schematic configuration example of an entire electronic device manufacturing apparatus.

FIG. 2 is a schematic view showing a schematic configuration example of an entire electronic device manufacturing apparatus different from the electronic device manufacturing apparatus shown in FIG. 1.

FIG. 3 is a schematic view showing a schematic configuration example of an entire extreme ultraviolet light generation apparatus of a comparative example.

FIG. 4 is a schematic view showing an extreme ultraviolet light generation chamber device in a cross section perpendicular to a trajectory of a droplet target in the comparative example.

FIG. 5 is a schematic view showing the extreme ultraviolet light generation chamber device in a cross section along the trajectory of the droplet target in the comparative example.

FIG. 6 is a schematic view of the extreme ultraviolet light generation chamber device of a first embodiment shown in the same manner as FIG. 4.

FIG. 7 is a schematic view of the extreme ultraviolet light generation chamber device of the first embodiment shown in the same manner as FIG. 5.

FIG. 8 is an enlarged view of a gas curtain forming device and a gas collection unit in FIG. 7.

FIG. 9 is a schematic view showing movement of debris in the first embodiment.

FIG. 10 is a schematic view of the extreme ultraviolet light generation chamber device of a first modification of the first embodiment shown in the same manner as FIG. 5.

FIG. 11 is a schematic view of the extreme ultraviolet light generation chamber device of a second modification of the first embodiment shown in the same manner as FIG. 5.

FIG. 12 is a schematic view of the extreme ultraviolet light generation chamber device of a third modification of the first embodiment shown in the same manner as FIG. 5.

FIG. 13 is a schematic view of the extreme ultraviolet light generation chamber device of a second embodiment shown in the same manner as FIG. 4.

### DESCRIPTION OF EMBODIMENTS

1. Overview
2. Description of electronic device manufacturing apparatus
3. Description of extreme ultraviolet light generation apparatus of comparative example
   3.1 Configuration
   3.2 Operation
   3.3 Problem
4. Description of extreme ultraviolet light generation chamber device of first embodiment
   4.1 Configuration
   4.2 Operation
   4.3 Effect
   4.4 Description of first modification
   4.5 Description of second modification
   4.6 Description of third modification
5. Description of extreme ultraviolet light generation chamber device of second embodiment
   5.1 Configuration
   5.2 Effect

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Overview

Embodiments of the present disclosure relate to an extreme ultraviolet light generation apparatus generating light having a wavelength of extreme ultraviolet (EUV) and an electronic device manufacturing apparatus. In the following, extreme ultraviolet light is referred to as EUV light in some cases.

### 2. Description of Electronic Device Manufacturing Apparatus

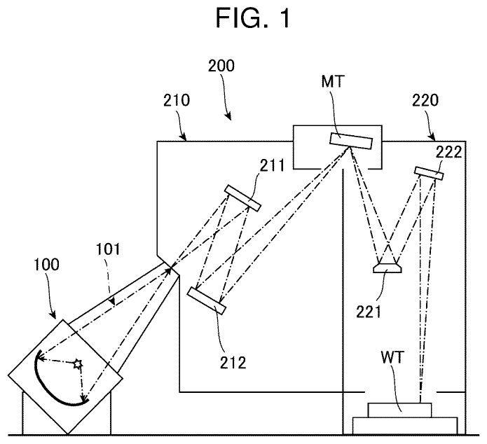

FIG. 1 is a schematic view showing a schematic configuration example of an entire electronic device manufacturing apparatus. The electronic device manufacturing apparatus shown in FIG. 1 includes an EUV light generation apparatus 100 and an exposure apparatus 200. The exposure apparatus 200 includes a mask irradiation unit 210 including a plurality of mirrors 211, 212 that configure a reflection optical system, and a workpiece irradiation unit 220 including a plurality of mirrors 221, 222 that configure a reflection optical system different from the reflection optical system of the mask irradiation unit 210. The mask irradiation unit 210 illuminates, via the mirrors 211, 212, a mask pattern of a mask table MT with EUV light 101 incident from the EUV light generation apparatus 100. The workpiece irradiation unit 220 images the EUV light 101 reflected by the mask table MT onto a workpiece (not shown) arranged on a workpiece table WT via the mirrors 221, 222. The workpiece is a photosensitive substrate such as a semiconductor wafer on which photoresist is applied. The exposure apparatus 200 synchronously translates the mask table MT and the workpiece table WT to expose the workpiece to the EUV light 101 reflecting the mask pattern. Through the exposure process as described above, a device pattern is transferred onto the semiconductor wafer, thereby a semiconductor device can be manufactured.

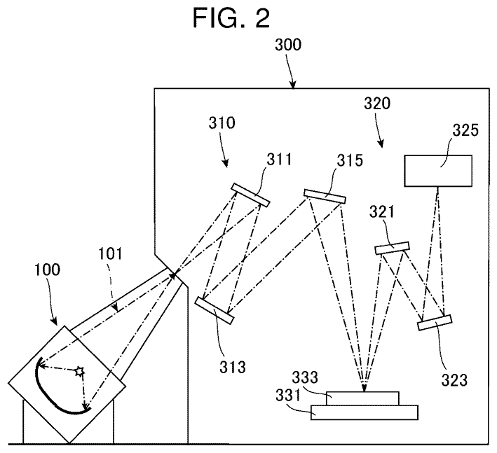

FIG. 2 is a schematic view showing a schematic configuration example of an entire electronic device manufacturing apparatus different from the electronic device manufacturing apparatus shown in FIG. 1. The electronic device manufacturing apparatus shown in FIG. 2 includes the EUV light generation apparatus 100 and an inspection apparatus 300. The inspection apparatus 300 includes an illumination optical system 310 including a plurality of mirrors 311, 313, 315 that configure a reflection optical system, and a detection optical system 320 including a detector 325 and a plurality of mirrors 321, 322 that configure a reflection optical system different from the reflection optical system of the illumination optical system 310. The illumination optical system 310 reflects, with the mirrors 311, 313, 315, the EUV light 101 incident from the EUV light generation apparatus 100 to illuminate a mask 333 placed on a mask stage 331. The mask 333 includes a mask blanks before a pattern is formed. The detection optical system 320 reflects, with the mirrors 321, 323, the EUV light 101 reflecting the pattern from the mask 333 and forms an image on a light receiving surface of the detector 325. The detector 325 having received the EUV light 101 acquires an image of the mask 333. The detector 325 is, for example, a time delay integration (TDI) camera. A defect of the mask 333 is inspected based on the image of the mask 333 acquired by the above-described process, and a mask suitable for manufacturing an electronic device is selected using the inspection result. Then, the electronic device can be manufactured by exposing and transferring the pattern formed on the selected mask onto the photosensitive substrate using the exposure apparatus 200.

### 3. Description of Extreme Ultraviolet Light Generation Apparatus of Comparative Example

### 3.1 Configuration

The EUV light generation apparatus 100 of a comparative example will be described. The comparative example of the present disclosure is an example recognized by the applicant as known only by the applicant, and is not a publicly known example admitted by the applicant. Further, the following description will be given with reference to the EUV light generation apparatus 100 that outputs the EUV light 101 to the exposure apparatus 200 as a subsequent process apparatus as shown in FIG. 1. Here, the EUV light generation apparatus 100 that outputs the EUV light 101 to the inspection apparatus 300 as a subsequent process apparatus as shown in FIG. 2 can obtain the same operation and effect.

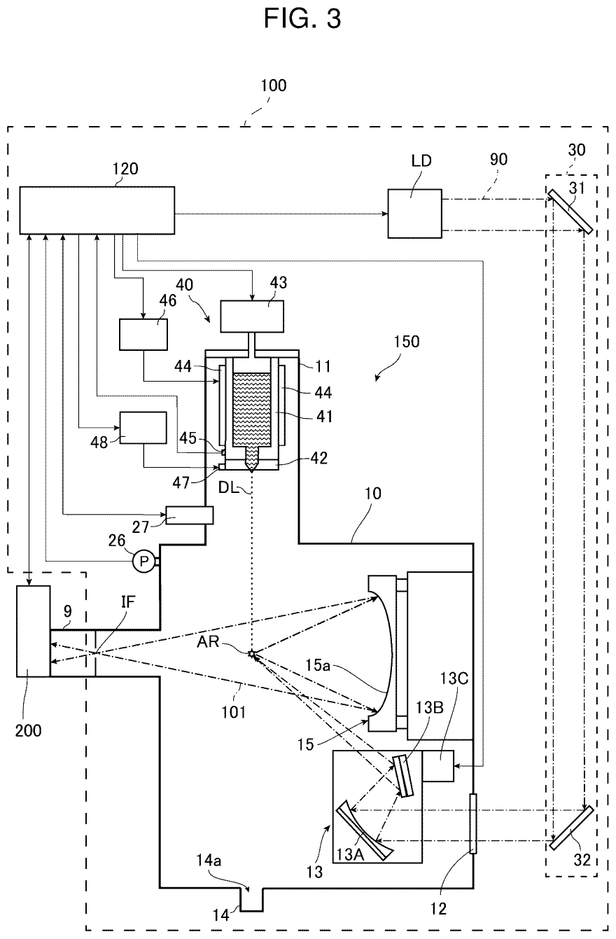

FIG. 3 is a schematic view showing a schematic configuration example of the entire EUV light generation apparatus 100 of the present example. As shown in FIG. 3, the EUV light generation apparatus 100 includes an EUV light generation chamber device 150, a laser device LD, and a laser light delivery optical system 30 as a main configuration. The EUV light generation chamber device 150 includes a chamber 10 and a processor 120 as a main configuration.

The chamber 10 is a sealable container. The chamber 10 includes a sub-chamber 11, and a target supply unit 40 is attached to the sub-chamber 11 to penetrate a wall of the sub-chamber 11. The target supply unit 40 includes a tank 41, a nozzle 42, and a pressure regulator 43 to supply a droplet target DL to the internal space of the chamber 10. The droplet target DL is sometimes abbreviated as a droplet or a target.

The tank 41 stores therein a target substance which becomes the droplet target DL. The target substance contains tin. The inside of the tank 41 is in communication with the pressure regulator 43 which adjusts the pressure in the tank 41. A heater 44 and a temperature sensor 45 are attached to the tank 41. The heater 44 heats the tank 41 with current applied from a heater power source 46. Through the heating, the target substance in the tank 41 melts. The temperature sensor 45 measures, via the tank 41, the temperature of the target substance in the tank 41. The pressure regulator 43, the temperature sensor 45, and the heater power source 46 are electrically connected to the processor 120.

The nozzle 42 is attached to the tank 41 and outputs the target substance. A piezoelectric element 47 is attached to the nozzle 42. The piezoelectric element 47 is electrically connected to a piezoelectric power source 48 and is driven by a voltage applied from the piezoelectric power source 48. The piezoelectric power source 48 is electrically connected to the processor 120. The target substance output from the nozzle 42 is formed into the droplet target DL through operation of the piezoelectric element 47.

The chamber 10 includes a target collection unit 14. The target collection unit 14 is a box body attached to the chamber 10 and communicates with the internal space of the chamber 10 through an opening 14a formed at the chamber 10. The opening 14a is arranged directly below the nozzle 42. The target collection unit 14 is a drain tank to collect any unnecessary droplet target DL having passed through the opening 14a and reaching the target collection unit 14.

The chamber 10 is provided with at least one through hole communicating with the chamber 10. The through hole is closed by a window 12. Pulse laser light 90 from the laser device LD passes through the window 12 and enters the chamber 10.

Further, a laser light concentrating optical system 13 is arranged at the internal space of the chamber 10. The laser light concentrating optical system 13 includes a laser light concentrating mirror 13A and a high reflection mirror 13B. The laser light concentrating mirror 13A reflects and concentrates the laser light 90 having transmitted through the window 12. The high reflection mirror 13B reflects the laser light 90 concentrated by the laser light concentrating mirror 13A. Positions of the laser light concentrating mirror 13A and the high reflection mirror 13B are adjusted by a laser light manipulator 13C so that a concentration position of the laser light 90 at the internal space of the chamber 10 coincides with a position specified by the processor 120. The light concentration position is adjusted to be a position directly below the nozzle 42, and when the target substance is irradiated with the laser light 90 at the light concentration position, plasma is generated from the target substance, and the EUV light 101 is radiated from the plasma. The region in which plasma is generated is sometimes referred to as a plasma generation region AR. The plasma generation region AR is a region having a radius of, for example, 40 mm about the plasma point and is located at the internal space of the chamber 10.

For example, an EUV light concentrating mirror 15 having a spheroidal reflection surface 15a is arranged at the internal space of the chamber 10. The EUV light concentrating mirror 15 includes, for example, a multilayer film in which silicon layers and molybdenum layers are alternately laminated, and reflects the EUV light 101 by the multilayer film. The EUV light concentrating mirror 15 is provided at a position not overlapping the laser light 90 at the internal space of the chamber 10. The reflection surface 15a reflects the EUV light 101 radiated from the plasma in the plasma generation region AR. The reflection surface 15a has a first focal point and a second focal point. The reflection surface 15a may be arranged such that, for example, the first focal point is located in the plasma generation region AR and the second focal point is located at an intermediate focal point IF.

The EUV light generation apparatus 100 includes a connection portion 9 providing communication between the internal space of the chamber 10 and the internal space of the exposure apparatus 200. A wall in which an aperture is formed is arranged in the connection portion 9. The wall is preferably arranged such that the aperture is located at the second focal point. The connection portion 9 is an outlet port of the EUV light 101 in the chamber 10, and the EUV light 101 is output from the connection portion 9 and enters the exposure apparatus 200.

Further, the EUV light generation apparatus 100 includes a pressure sensor 26 and a detection unit 27 as a target sensor. The pressure sensor 26 and the detection unit 27 are attached to the chamber 10 and are electrically connected to the processor 120. The pressure sensor 26 measures the pressure at the internal space of the chamber 10 and outputs a signal indicating the measured pressure to the processor 120.

The detection unit 27 has, for example, an imaging function, and detects the presence, trajectory, position, velocity, and the like of the droplet target DL output from the nozzle hole of the nozzle 42 in accordance with an instruction from the processor 120. The detection unit 27 may be arranged inside the chamber 10, or may be arranged outside the chamber 10 and detect the droplet target DL through a window (not shown) arranged on a wall of the chamber 10. The detection unit 27 includes a light receiving optical system (not shown) and an imaging unit (not shown) such as a charge-coupled device (CCD) or a photodiode. In order to improve the detection accuracy of the droplet target DL, the light receiving optical system forms an image of the trajectory of the droplet target DL and the periphery thereof on a light receiving surface of the imaging unit. When the droplet target DL passes through a light concentration region of a light source (not shown) arranged to improve contrast in the field of view of the detection unit 27, the imaging unit detects a change of the light passing through the trajectory of the droplet target DL and the periphery thereof. The imaging unit converts the detected light change into a signal related to the image data of the droplet target DL. The imaging unit outputs the converted signal to the processor 120.

The laser device LD includes a master oscillator being a light source to perform burst operation. The master oscillator outputs the pulse laser light 90 in a burst-on duration. The master oscillator is, for example, a solid-state laser device that excites a YAG crystal to which neodymium (Nd) or ytterbium (Yb) is added, or a laser device that outputs the laser light 90 by exciting a gas in which helium, nitrogen, or the like is mixed in a carbon dioxide gas through electric discharge. Alternatively, the master oscillator may be a quantum cascade laser device. The master oscillator may output the pulse laser light 90 by a Q switch system. Further, the master oscillator may include an optical switch, a polarizer, and the like. In the burst operation, the pulse laser light 90 is continuously output at a predetermined repetition frequency in the burst-on duration and the output of the laser light 90 is stopped in a burst-off duration. The laser device LD may include an amplifier that amplifies the laser light output from the master oscillator.

The laser device LD may include a prepulse laser device which outputs prepulse laser light for misting the droplet target DL, and a main pulse laser device which outputs main pulse laser light for turning the misted droplet target DL into plasma. In this case, the laser light 90 includes the prepulse laser light and the main pulse laser light. For example, the prepulse laser device is a YAG laser device which outputs the prepulse laser light having a wavelength of 1.06 μm. Further, for example, the main pulse laser device is a YAG laser device which outputs the main pulse laser light having a wavelength of 1.06 μm or a CO₂ laser device which outputs the main pulse laser light having a wavelength of 10.6 μm.

A travel direction of the laser light 90 output from the laser device LD is adjusted by the laser light delivery optical system 30. The laser light delivery optical system 30 includes a plurality of mirrors 31, 32 for adjusting the travel direction of the laser light 90. The position of at least one of the mirrors 31, 32 is adjusted by an actuator (not shown). Owing to that the position of at least one of the mirrors 31, 32 is adjusted, the laser light 90 can appropriately propagate to the internal space of the chamber 10 through the window 12.

The processor 120 of the present disclosure is a processing device including a storage device in which a control program is stored and a central processing unit (CPU) that executes the control program. The processor 120 is specifically configured or programmed to perform various processes included in the present disclosure and controls the entire EUV light generation apparatus 100. The processor 120 receives a signal related to the pressure at the internal space of the chamber 10, which is measured by the pressure sensor 26, a signal related to image data of the droplet target DL captured by the detection unit 27, a burst signal instructing the burst operation from the exposure apparatus 200, and the like. The processor 120 processes the various signals, and may control, for example, the timing at which the droplet target DL is output, the output direction of the droplet target DL, and the like. Further, the processor 120 may control the output timing of the laser device LD, the travel direction and the concentration position of the laser light 90, and the like. Such various kinds of control described above are merely exemplary, and other control may be added as necessary, as described later.

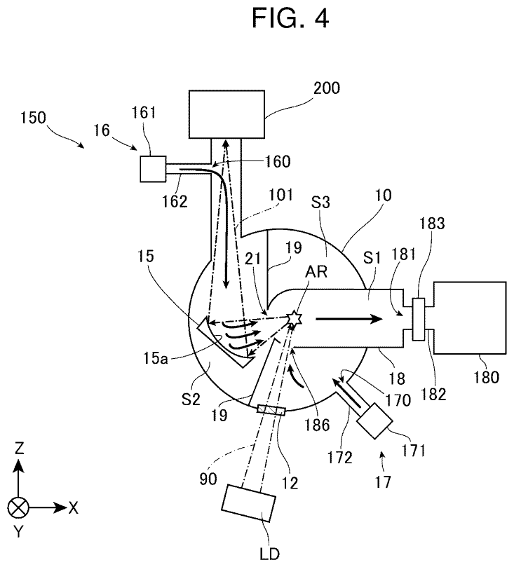

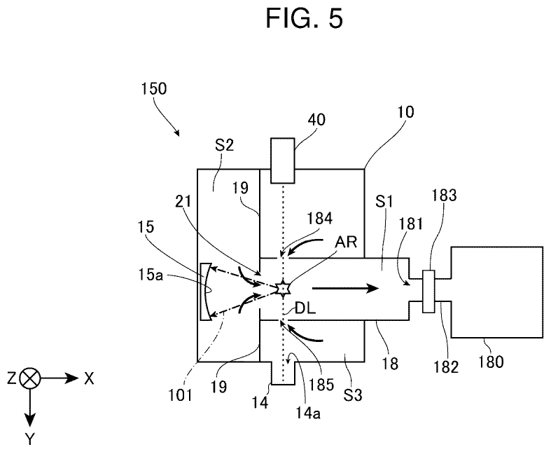

FIG. 4 is a schematic view including a cross section of the chamber 10 perpendicular to the trajectory of the droplet target DL in the comparative example, and FIG. 5 is a schematic view including a cross section of the chamber 10 along the trajectory of the droplet target DL. In FIG. 4, for simplification of illustration, the laser light concentrating mirror 13A and the high reflection mirror 13B are omitted, and a travel path of the laser light 90 from the window 12 to the plasma generation region AR is shown by dot chain lines. In the following, a direction along the trajectory of the droplet target DL may be referred to as a Y direction, a direction from the plasma generation region AR toward the first exhaust device 180 and perpendicular to the Y direction may be referred to as an X direction, and a direction perpendicular to the Y direction and the X direction may be referred to as a Z direction.

The EUV light generation apparatus 100 includes a cylindrical first partition wall 18 linearly extending from the internal space of the chamber 10 to the external space of the chamber 10. The first partition wall 18 is made of, for example, stainless steel, metal molybdenum, or the like. The first partition wall 18 surrounds the plasma generation region AR. Among mutually opposed openings of the first partition wall 18, the opening located at the internal space of the chamber 10 is a first opening 21. The first opening 21 is provided on an optical path through which the EUV light 101 propagates from the plasma generation region AR to the EUV light concentrating mirror 15. The opening located outside the chamber 10 is a first gas exhaust port 181.

Further, the EUV light generation apparatus 100 includes a planar second partition wall 19 at the internal space of the chamber 10. The second partition wall 19 is made of, for example, stainless steel, metal molybdenum, or the like. The second partition wall 19 is arranged between the region on the EUV light concentrating mirror 15 side and the region on the outer side of the first partition wall 18. The second partition wall 19 is connected to an end part of the first partition wall 18 located at the internal space of the chamber 10. Further, the second partition wall 19 is provided with an opening at a position overlapping with the first opening 21. Therefore, it can be understood that the first opening 21 is provided in the first partition wall 18 and the second partition wall 19. In FIG. 3, the first partition wall 18 and the second partition wall 19 are not shown.

In the present example, among the internal space of the chamber 10, the space on the EUV light concentrating mirror 15 side with respect to the second partition wall 19 is defined as a second space S2, and the internal space of the first partition wall 18 is defined as a first space S1. Further, the space opposite to the EUV light concentrating mirror 15 with respect to the second partition wall 19 and outside the first partition wall 18 of the chamber 10 is defined as a third space S3. That is, the first partition wall 18 isolates the first space S1 and the third space S3, and the second partition wall 19 isolates the second space S2 and the third space S3.

The EUV light 101 generated from the plasma in the plasma generation region AR can be incident on the EUV light concentrating mirror 15 arranged in the second space S2 from the first space S1 through the first opening 21.

The first opening 21 faces the first gas exhaust port 181, and the plasma generation region AR is located between the first opening 21 and the first gas exhaust port 181. Therefore, the plasma generation region AR is located in the first space S1. The first gas exhaust port 181 is connected to a first exhaust device 180 including an exhaust pump through a pipe 182. Further, a first valve 183 whose opening degree can be changed is provided at a pipe 182 connecting the first space S1 and the first exhaust device 180.

A droplet supply opening 184, a droplet discharge opening 185, and a second opening 186 are provided on a side surface of the first partition wall 18. The second opening 186 is provided on an optical path on which the laser light 90 propagates to the plasma generation region AR at the internal space of the chamber 10, and the laser light 90 enters the plasma generation region AR from the third space S3 through the second opening 186. The droplet supply opening 184 and the droplet discharge opening 185 are provided on the trajectory of the droplet target DL and face each other. The droplet target DL is supplied from the target supply unit 40 to the plasma generation region AR through the droplet supply opening 184. The droplet discharge opening 185 faces the opening 14a connected to the target collection unit 14, and the droplet target DL that has passed through the plasma generation region AR enters the target collection unit 14 through the droplet discharge opening 185. In the present example, the areas of the droplet supply opening 184 and the droplet discharge opening 185 are substantially the same as each other and are larger than the area of the second opening 186. The first partition wall 18 surrounds the plasma generation region AR except on the trajectory of the droplet target DL at the internal space of the chamber 10, the optical path of the laser light 90 to the plasma generation region AR at the internal space, and the optical path of the EUV light 101 from the plasma generation region AR.

Further, the window 12 is provided in a wall of the chamber 10 on the third space S3 side, and closes a through hole communicating with the third space S3. The laser light 90 is radiated to the plasma generation region AR through the second opening 186 from the window 12.

A first etching gas supply unit 17 is connected to the chamber 10. The first etching gas supply unit 17 supplies an etching gas to the first space S1 through the third space S3. The first etching gas supply unit 17 includes a first gas supply port 170. The first gas supply port 170 is provided in a wall of the chamber 10 on the third space S3 side. The etching gas from the first gas supply port 170 is supplied from the third space S3 to the first space S1 through the second opening 186, the droplet supply opening 184, the droplet discharge opening 185, and the like. The etching gas contains a hydrogen gas, and the etching gas of the present example is a hydrogen gas having a hydrogen concentration of 100% in effect. In the present example, the first etching gas supply unit 17 further includes a hydrogen tank 171 and a gas pipe 172. The first etching gas supply unit 17 supplies the hydrogen gas in the hydrogen tank 171 to the third space S3 from the first gas supply port 170 through the gas pipe 172. A supply gas flow rate adjustment unit (not shown) being a valve may be provided at the gas pipe 172. The first etching gas supply unit 17 is electrically connected to the processor 120 and controlled by the processor 120. For example, when the supply gas flow rate adjustment unit is provided, the processor 120 controls the supply gas flow rate adjustment unit to adjust the flow rate of the etching gas to be supplied to the first space S1. Here, the etching gas may be, for example, a balance gas having a hydrogen gas concentration of about 3%. In this case, the balance gas includes, for example, a nitrogen (N₂) gas or an argon (Ar) gas.

Further, a second etching gas supply unit 16 is connected to the chamber 10. The second etching gas supply unit 16 supplies, to the second space S2, the etching gas similar to the etching gas supplied by the first etching gas supply unit 17. The second etching gas supply unit 16 includes a second gas supply port 160 provided in a wall of the chamber 10 on the second space S2 side. Here, the second gas supply port 160 is provided at a cylindrical portion surrounding the optical path on which the EUV light 101 propagates from the EUV light concentrating mirror 15 to the exposure apparatus 200. The etching gas supplied from the second gas supply port 160 flows in the second space S2 in a direction opposite to the direction in which the EUV light 101 enters the exposure apparatus 200 from the EUV light concentrating mirror 15. In the present example, the second etching gas supply unit 16 further includes a hydrogen tank 161 and a gas pipe 162. A supply gas flow rate adjustment unit (not shown) being a valve may be provided at the gas pipe 162. The second etching gas supply unit 16 is electrically connected to the processor 120 and controlled by the processor 120. For example, when the supply gas flow rate adjustment unit is provided, the processor 120 controls the supply gas flow rate adjustment unit to adjust the flow rate of the etching gas to be supplied to the second space S2.

Since the target substance is tin as described above, tin fine particles and tin charged particles are generated when the target substance is turned into plasma in the plasma generation region AR by being irradiated with the laser light 90. Further, hydrogen contained in the etching gas is turned into hydrogen radicals due to the energy of the EUV light 101. Tin constituting the fine particles and the charged particles reacts with hydrogen radicals. When tin reacts with hydrogen radicals, stannane (SnH₄) gas at room temperature is generated. In FIGS. 4 and 5, the flow of the etching gas supplied from the second etching gas supply unit 16 to the reflection surface 15a of f the EUV light concentrating mirror 15 is indicated by arrows. The flow rate of the etching gas supplied from the second etching gas supply unit 16 to the second space S2 is preferably, for example, 20 nlm or more and 60 nlm or less. Further, the flow rate of the etching gas supplied from the first etching gas supply unit 17 to the third space S3 is preferably, for example, 20 nlm or more and 60 nlm or less. Here, nlm represents the volume of the etching gas flowing per minute converted to that at 0° C. and 1 atm.

When the target substance is turned into plasma in the plasma generation region AR, the residual gas as an exhaust gas is generated in the first space S1. The residual gas contains tin fine particles and charged particles generated through the plasma generation from the target substance, stannane generated through the reaction of the tin fine particles and charged particles with the etching gas, and an unreacted etching gas. Some of the charged particles are neutralized, and the residual gas contains the neutralized charged particles as well. The first exhaust device 180 exhausts the residual gas in the first space S1 to the outside of the chamber 10 together with the residual gas flowing from the second space S2 to the first space S1.

### 3.2 Operation

Next, operation of the EUV light generation apparatus 100 of the comparative example will be described.

In the EUV light generation apparatus 100, for example, at the time of new installation or maintenance or the like, atmospheric air at the internal space of the chamber 10 is exhausted. At this time, purging and exhausting of the internal space of the chamber 10 may be repeated for exhausting atmospheric components. For example, an inert gas such as nitrogen or argon is preferably used for the purge gas. Thereafter, when the pressure at the internal space of the chamber 10 becomes equal to or lower than a predetermined pressure, the processor 120 starts introducing the etching gas into the first space S1 of the chamber 10 through the first gas supply port 170 of the first etching gas supply unit 17, and starts introducing the etching gas into the second space S2 of the chamber 10 through the second gas supply port 160 of the second etching gas supply unit 16. At this time, the processor 120 may control the first etching gas supply unit 17, the second etching gas supply unit 16, and the first exhaust device 180 so that the pressure at the internal space of the chamber 10 is maintained at the predetermined pressure. Thereafter, the processor 120 waits until a predetermined time elapses from the start of introduction of the etching gas into the first space S1 and the second space S2.

Further, the first exhaust device 180 exhausts the gas at the internal space of the chamber 10 from the first gas exhaust port 181, and maintains the pressure at the internal space of the chamber 10 substantially constant.

In order to heat and maintain the target substance in the tank 41 to and at a predetermined temperature equal to or higher than the melting point, the processor 120 causes the heater power source 46 to supply current to the heater 44 to increase temperature of the heater 44. In this case, the processor 120 controls the temperature of the target substance to the predetermined temperature by adjusting a value of the current supplied from the heater power source 46 to the heater 44 based on an output from the temperature sensor 45. When the target substance is tin, the predetermined temperature is equal to or higher than 231.93° C. being the melting point of tin and, for example, is 240° C. or higher and 290° C. or lower. Thus, the preparation for outputting the droplet target DL is completed.

When the preparation is completed, the processor 120 causes the pressure regulator 43 to supply the inert gas from a gas supply source (not shown) to the tank 41 and to adjust the pressure in the tank 41 so that the melted target substance is output through the nozzle hole of the nozzle 42 at a predetermined velocity. Under this pressure, the target substance is output to the internal space of the chamber 10 through the nozzle hole of the nozzle 42. The target substance output through the nozzle hole may be in the form of jet. At this time, the processor 120 causes the piezoelectric power source 48 to apply a voltage having a predetermined waveform to the piezoelectric element 47 to generate the droplet target DL. The piezoelectric power source 48 applies the voltage so that the waveform of the voltage value becomes, for example, a sine a wave, rectangular wave, or a sawtooth wave. Vibration of the piezoelectric element 47 can propagate through the nozzle 42 to the target substance to be output through the nozzle hole of the nozzle 42. The target substance is divided at a predetermined cycle by the vibration into liquid droplet targets DL. The diameter of the droplet target DL is approximately 10 μm or more and 30 μm or less.

When the droplet target DL is output, the droplet target DL passes through the droplet supply opening 184 and travels to the plasma generation region AR. The detection unit 27 detects the passage timing of the droplet target DL passing through a predetermined position of the internal space of the chamber 10. The processor 120 outputs a trigger signal to control the timing of outputting the laser light 90 from the laser device LD based on the signal from the detection unit 27 so that the droplet target DL is irradiated with the laser light 90. The trigger signal output from the processor 120 is input to the laser device LD. When the trigger signal is input, the laser device LD outputs the pulse laser light 90.

The output laser light 90 enters the laser light concentrating optical system 13 through the laser light delivery optical system 30 and the window 12. The laser light 90 travels from the laser light concentrating optical system 13 toward the plasma generation region AR through the second opening 186. Then, the droplet target DL is irradiated with the laser light 90 in the plasma generation region AR. At this time, the processor 120 controls the laser light manipulator 13C of the laser light concentrating optical system 13 so that the laser light 90 is concentrated in the plasma generation region AR. Thus, the droplet target DL is irradiated in the plasma generation region AR with the laser light 90 concentrated by the laser light concentrating mirror 13A. Plasma is generated by the irradiation, and light including the EUV light 101 is radiated from the plasma.

Among the light including the EUV light 101 generated in the plasma generation region AR, a part of the EUV light 101 travels to the EUV light concentrating mirror 15 after passing through the first opening 21, is concentrated at the intermediate focal point IF by the EUV light concentrating mirror 15, and then, enters the exposure apparatus 200 from the connection portion 9.

As described above, the first etching gas supply unit 17 supplies the etching gas to the first space S1 of the chamber 10 through the first gas supply port 170, and the second etching gas supply unit 16 supplies the etching gas to the second space S2 of the chamber 10 through the second gas supply port 160. Hydrogen contained in the etching gas is turned into hydrogen radicals due to the energy of the EUV light 101. Therefore, when tin is deposited on the reflection surface 15a of the EUV light concentrating mirror 15, on the inner peripheral surface of the first partition wall 18, or the like, at least a part of the tin reacts with hydrogen radicals to become stannane, and is removed from the reflection surface 15a, the inner peripheral surface, or the like. The etching gas and the stannane in the second space S2 mainly flow into the first space S1 through the first opening 21. The first exhaust device 180 sucks, together with the residual gas in the first space S1, through the first gas exhaust port 181, the etching gas and the stannane having flowed into the first space S1 from the second space S2. Accordingly, the gas in the first space S1 and the second space S2 is exhausted to the outside of the chamber 10. The gas suctioned by the first exhaust device 180 is subjected to predetermined exhaust treatment such as detoxification.

### 3.3 Problem

When the target substance is turned into plasma by being irradiated with the laser light 90, tin fine particles, charged particles, neutral particles produced through neutralization of the charged particles, and the like are generated and scattered. The tin fine particles, charged particles, neutral particles produced through neutralization of the charged particles, and the like scattered from the droplet target DL by being irradiated with the laser light 90 are sometimes referred to as debris.

When debris adheres to the reflection surface 15a, reflectance of the EUV light 101 decreases, and there is a fear that the power of the EUV light 101 output from the EUV light generation apparatus 100 decreases. Therefore, the EUV light generation apparatus 100 suppresses diffusion of the debris from the first space S1 to the second space S2 by causing the particles of the etching gas to collide with the debris and decelerating or stopping the debris by the flow of the etching gas. The number of collisions between the particles of the etching gas and the debris per unit distance is generally determined by the density of the particles of the etching gas. For this reason, the EUV light generation apparatus 100 needs to increase the pressure of the etching gas to increase the number of collisions between the particles of the etching gas and the debris. For example, the EUV light generation apparatus 100 sets the pressure of the etching gas in the chamber 10 to be equal to or higher than 100 Pa to stop the debris particles between the plasma generation region AR and the EUV light concentrating mirror 15.

However, since the EUV light 101 generated from the plasma generation region AR is absorbed by hydrogen on the optical path, the EUV light 101 absorbed by hydrogen contained in the etching gas is increased when the pressure of the etching gas is increased. Therefore, the power of the EUV light 101 output from the EUV light generation apparatus 100 is reduced. Further, to suppress adhesion of the debris to the reflection surface 15a without increasing the pressure of the etching gas, it is conceivable to increase the distance between the plasma generation region AR and the EUV light concentrating mirror 15 to suppress the adhesion of the debris to the reflection surface 15a. However, in this case, the size of the EUV light generation apparatus 100 is increased.

Therefore, the following embodiments exemplify an EUV light generation chamber device 150 which can suppress decrease in the power of the EUV light output from the EUV light generation apparatus 100 by achieving both suppressing adhesion of the debris to the reflection surface 15a and suppressing decrease of the power of the EUV light 101 due to the etching gas.

### 4. Description of Extreme Ultraviolet Light Generation Chamber Device of First Embodiment

The configuration of the EUV light generation chamber device 150 of a first embodiment will be described. Any component same as that described above is denoted by an identical reference sign, and duplicate description thereof is omitted unless specific description is needed.

### 4.1 Configuration

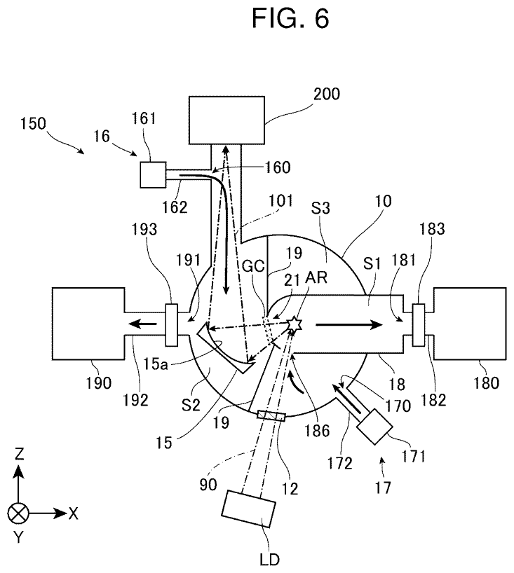

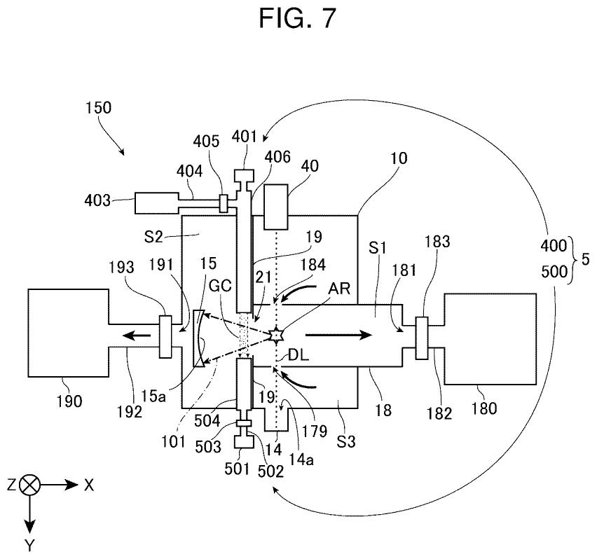

FIG. 6 is a schematic view of the EUV light generation chamber device 150 of the present embodiment shown in the same manner as FIG. 4, and FIG. 7 is a schematic view of the EUV light generation chamber device 150 of the present embodiment shown in the same manner as FIG. 5.

The EUV light generation chamber device 150 of the present embodiment mainly differs from the EUV light generation chamber device 150 of the comparative example in including a second exhaust device 190 and a gas curtain forming device 5.

In the present embodiment, a second gas exhaust port 191 is provided in a wall of the chamber 10 on the second space S2 side. The second gas exhaust port 191 is connected to the second exhaust device 190 including an exhaust pump through a pipe 192. Further, a second valve 193 is provided at the pipe 192 that connects the second space S2 and the second exhaust device 190. The opening degree of the second valve 193 can be changed. The second exhaust device 190 exhausts the residual gas from the second space S2 through the pipe 192.

The first exhaust device 180, the first gas exhaust port 181, the pipe 182, the first valve 183, the second exhaust device 190, the second gas exhaust port 191, the pipe 192, and the second valve 193 configure a gas exhaust unit that exhausts the residual gas from the chamber 10.

Further, the first etching gas supply unit 17 and the second etching gas supply unit 16 configure an etching gas supply unit that supplies the etching gas to the chamber 10.

The gas curtain forming device 5 includes a gas injection unit 400 that injects gas at a supersonic velocity, and a gas collection unit 500 that collects the gas.

The gas injection unit 400 injects the gas to form a gas curtain GC that closes at least a part of the first opening 21. In the present embodiment, the gas injection unit 400 injects the gas in the Y-axis direction to form the gas curtain GC. The gas curtain GC intersects the optical path of the EUV light 101 propagating from the plasma generation region AR to the EUV light concentrating mirror 15. Further, in the present embodiment, since the gas injection unit 400 forms the gas curtain GC immediately adjacent to the second partition wall 19, the first space S1 is a space on the plasma generation region AR side with respect to the gas curtain GC, and the second space S2 is a space on the EUV light concentrating mirror 15 side with respect to the gas curtain GC.

The gas collection unit 500 is arranged at a position advanced in the direction in which the gas is injected from the gas injection unit 400. The gas collection unit 500 collects the gas configuring the gas curtain GC and discharges the gas to the outside.

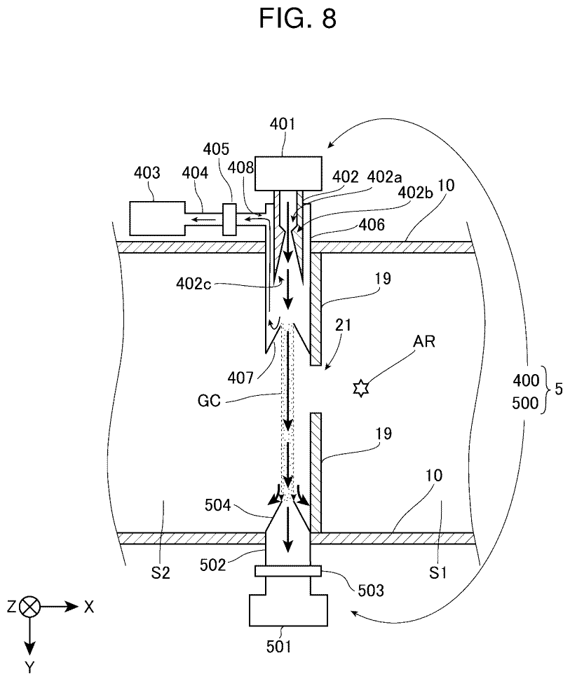

FIG. 8 is an enlarged view of the gas injection unit 400 and the gas collection unit 500. As shown in FIG. 8, the gas injection unit 400 includes a gas supply unit 401, a Laval nozzle 402, a third exhaust device 403, a pipe 404, a third valve 405, a shroud 406, and a first skimmer 407 as a main configuration.

The gas supply unit 401 supplies the gas to configure the gas curtain GC. The gas supply unit 401 includes a regulator for adjusting the pressure of the gas to be supplied and a gas source such as a cylinder for storing the gas. The gas supply unit 401 is electrically connected to the processor 120 and controlled by the processor 120. The processor 120 controls the regulator to regulate the pressure of the gas to be supplied to the inside of the Laval nozzle 402. The gas supply unit 401 is connected to the Laval nozzle 402. A pipe may be provided between the gas supply unit 401 and the Laval nozzle 402.

The gas to be supplied by the gas supply unit 401 includes hydrogen. The gas to be supplied by the gas supply unit 401 may be the gas same as or different from the etching gas supplied by the first etching gas supply unit 17 and the second etching gas supply unit 16. However, the gas is preferably 100% hydrogen from a viewpoint of suppressing absorption of the EUV light 101 by the gas curtain GC.

The Laval nozzle 402 has a flow path having a non-circular cross section in a plane perpendicular to the longitudinal direction of the Laval nozzle 402, that is, in the XZ plane. For example, the cross section perpendicular to the longitudinal direction of the Laval nozzle 402 may be rectangular, racetrack-like, oval, or the like, but is not limited to a specific shape. The longitudinal direction of the cross section of the Laval nozzle 402 in the XZ plane is substantially parallel to the Z direction, and is substantially parallel to an imaginary plane that closes the first opening 21. Assuming that the imaginary plane that closes the first opening 21 is substantially parallel to the YZ plane, the length of the Laval nozzle 402 in the Z direction is preferably, for example, equal to or larger than the size of the first opening 21 in the Z direction. The Laval nozzle 402 includes a gas compression portion 402a whose cross-sectional area on the XZ plane decreases as proceeding in the direction in which the gas is injected, and a gas expansion portion 402c whose cross-sectional area on the XZ plane increases as proceeding in the direction in which the gas is injected. A throat 402b between the gas compression portion 402a and the gas expansion portion 402c has, for example, a width of 0.5 mm to 1 mm inclusive.

The shroud 406 extends linearly from the external space of the chamber 10 to the internal space of the chamber 10. The lower end of the shroud 406 located inside the chamber 10 is open and protrudes in the second space S2. Further, a part of the side surface of the shroud 406 may be in contact with the second partition wall 19. The Laval nozzle 402 is arranged at the internal space of the shroud 406, and a gap is formed between the side wall in the shroud 406 and the Laval nozzle 402. The shroud 406 extends toward the direction in which the gas is injected from the distal end of the gas expansion portion 402c of the Laval nozzle 402. A portion of the shroud 406 located outside the chamber 10 has an opening to which the Laval nozzle 402 is fixed.

In the shroud 406, the first skimmer 407 is fixed to a position proceeding in the direction in which the gas is injected from the Laval nozzle 402. In the present embodiment, the first skimmer 407 is fixed to an end part of the shroud 406 at the internal space of the chamber 10. The opening of the first skimmer 407 is configured such that a cross-sectional area thereof perpendicular to the direction in which the gas is injected, that is, a cross-sectional area along the XZ plane increases as proceeding in the direction in which the gas is injected. The first skimmer 407 has a flow path having a non-circular cross section on the XZ plane. For example, the shape of the cross section of the first skimmer 407 on the XZ plane may be rectangular, racetrack-like, oval, or the like, but is not limited to a specific shape. The longitudinal direction of the cross section of the first skimmer 407 on the XZ plane is substantially parallel to a plane perpendicular to the direction from the plasma generation region AR to the EUV light concentrating mirror 15 through the first opening 21. Accordingly, the longitudinal direction of the cross section of the first skimmer 407 on the XZ plane is substantially parallel to the Z direction. The longitudinal cross section of the first skimmer 407 on the XZ plane is substantially parallel to the Laval nozzle 402. Assuming that the imaginary plane that closes the first opening 21 is substantially parallel to the YZ plane, the length of the first skimmer 407 in the Z direction is approximately the same as the length of the first opening 21 in the Z direction. The first skimmer 407 has a width of about 1 mm.

A third gas exhaust port 408 is provided in the side wall of the shroud 406. The third gas exhaust port 408 is provided at a position opposite to the direction in which the gas is injected with respect to the distal end of the Laval nozzle 402. The third gas exhaust port 408 is connected to the third exhaust device 403 including an exhaust pump through the pipe 404.

The third valve 405 is provided at the pipe 404 that connects the internal space of the shroud 406 and the third exhaust device 403. The opening degree of the third valve 405 can be changed. When the third valve 405 is opened, the third exhaust device 403 exhausts, through the pipe 404, the gas that has not passed through the first skimmer 407 from the inside of the shroud 406.

The gas collection unit 500 includes a fourth exhaust device 501, a pipe 502, a fourth valve 503, and a second skimmer 504 as a main configuration.

The second skimmer 504 is arranged at a position in the second space S2 proceeding in the direction in which the gas is injected from the gas injection unit 400. The opening of the second skimmer 504 is configured such that a cross-sectional area thereof on the XZ plane increases as proceeding in the direction in which the gas is injected. The second skimmer 504 has a flow path having a non-circular cross section on the XZ plane. For example, the shape of the cross section of the second skimmer 504 on the XZ plane may be rectangular, racetrack-like, oval, or the like, but is not limited to a specific shape. Further, the cross-sectional shape of the second skimmer 504 on the XZ plane may be the same as or different from the cross-sectional shape of the first skimmer 407 on the XZ plane. The longitudinal direction of the cross section of the second skimmer 504 on the XZ plane is substantially parallel to the longitudinal direction of the cross section of the first skimmer 407 on the XZ plane. The longitudinal length of the cross section of the second skimmer 504 on the XZ plane is comparable to the longitudinal length of the cross section of the first skimmer 407 on the XZ plane.

The pipe 502 is connected to the second skimmer 504. The pipe 502 extends linearly from the internal space of the chamber 10 to the external space of the chamber 10. An end part of the pipe 502 located inside the chamber 10 is connected to the second skimmer 504. An end part of the pipe 502 located outside the chamber 10 is connected to the fourth exhaust device 501 including an exhaust pump.

The fourth valve 503 is provided at the pipe 502 that connects the internal space of the second skimmer 504 and the fourth exhaust device 501. The opening degree of the fourth valve 503 can be changed. The third exhaust device 403 exhausts, through the pipe 502, the gas that has entered the second skimmer 504.

Here, as long as one end of the second skimmer 504 having a small cross-sectional area on the XZ plane protrudes into the second space S2, the other end may exist between the inner wall and the outer wall of the chamber 10, or may protrude to the outside of the chamber 10.

### 4.2 Operation

Next, operation of the EUV light generation apparatus 100 of the present embodiment will be described.

Similarly to the comparative example, in the EUV light generation apparatus 100, the processor 120 introduces the etching gas into the internal space of the chamber 10 from the first etching gas supply unit 17 and the second etching gas supply unit 16, for example, at the time of new introduction or maintenance or the like.

Further, the gas exhaust unit exhausts the gas from the first space S1 and the second space S2 so that the pressure in the second space S2 becomes lower than the pressure in the first space S1. For example, the opening degree of the first valve 183 and the opening degree of the second valve 193 are adjusted so that the pressure in the second space S2 becomes lower than the pressure in the first space S1. Further, the etching gas supply unit may control the flow rate of the etching gas to be supplied to the first space S1 and the second space S2 so that the pressure in the second space S2 becomes lower than the pressure in the first space S1. Further, the etching gas supply unit and the gas exhaust unit may be operated synchronously with each other by the processor 120 so that the pressure in the second space S2 becomes lower than the pressure in the first space S1.

Further, the processor 120 controls the gas supply unit 401 to cause the gas supply unit 401 to supply the gas to the Laval nozzle 402 prior to the pressure adjustment after exhausting of the first space S1 and the second space S2. The supply pressure of the gas from the gas supply unit 401 to the Laval nozzle 402 is adjusted by the regulator, and is, for example, 1 kPa or higher. At this time, the third valve 405 and the fourth valve 503 are not closed.

The gas supplied from the gas supply unit 401 to the Laval nozzle 402 is compressed by the gas compression portion 402a of the Laval nozzle 402, and the velocity of the gas becomes approximately sonic at the throat 402b. The gas travels to the gas expansion portion 402c through the throat 402b, and the velocity of the gas becomes supersonic at the gas expansion portion 402c.

Here, the sonic velocity denotes the sonic velocity in the space through which the gas passes. For example, when the pressure is set to 10 Pa and the temperature is set to 300 K in the hydrogen gas, the sonic velocity a of a perfect gas is calculated to 1316 m/s by the equation below, where the specific heat ratio γ is 1.4, the gas constant is represented by R, the universal gas constant R₀ is 8314.5 J/kmol·K, the molecular weight M is 2.016 kg/kmol, and the temperature T is 300 K.

$$a = {( γ \times R \times T )}^{( 1 / 2 )} = {( γ \times ( {R}_{0} / M ) \times T )}^{( 1 / 2 )} = 1316 ( m / s )$$

The gas having the supersonic velocity is discharged into the shroud 406 from the gas expansion portion 402c of the Laval nozzle 402 with directivity in the Y-axis direction. The gas discharged into the shroud 406 travels in the Y-axis direction. The gas traveling in the Y-axis direction is partially extracted by the opening of the first skimmer 407 and is injected into the second space S2 at the supersonic velocity.

The gas not injected from the opening of the first skimmer 407 remains in the shroud 406. The third exhaust device 403 exhausts the gas remaining in the shroud 406 from the third gas exhaust port 408 through the pipe 404. The third exhaust device 403 may operate under control of the processor 120 or may operate in accordance with operation of an operator or the like.

Here, the gas remaining in the shroud 406 is desirably a molecular flow having a low gas density to suppress disturbance of the gas having directivity injected from the Laval nozzle 402. For example, the pressure in the shroud 406 is maintained approximately at 10 Pa by the third valve 405.

The gas injected from the opening of the first skimmer 407 travels in the Y-axis direction in the second space S2 to form the gas curtain GC covering at least a part of the first opening 21. The gas curtain GC covers at least a part of the first opening 21 to suppress various gases, debris, and the like from moving between the first space S1 and the second space S2. The gas curtain GC may maintain a pressure difference between the first space S1 and the second space S2. From the viewpoint of suppressing the movement of various gases, debris, and the like between the first space S1 and the second space S2, the gas curtain GC preferably covers the entire first opening 21.

The gas injected from the opening of the first skimmer 407 and traveling in the Y-axis direction in the second space S2 travels to the inside of the second skimmer 504 from the opening of the second skimmer 504. Since the velocity of the gas injected from the opening of the first skimmer 407 exceeds the sonic velocity, the directivity of the gas is high. Therefore, a large amount of the gas flows from the opening of the second skimmer 504 into the second skimmer 504.

The fourth exhaust device 501 exhausts the gas that has flowed into the second skimmer 504 through the pipe 502. The fourth exhaust device 501 may operate under control of the processor 120 or may operate in accordance with operation of an operator or the like.

For example, the pressure in the second skimmer 504 is adjusted to be equal to or less than the pressure in the second space S2 to prevent the gas from flowing back from the second skimmer 504 to the second space S2. When the pressure in the second space S2 is, for example, 30 Pa, the pressure in the second skimmer 504 is adjusted to be lower than 30 Pa.

For example, when the length of the optical path from the EUV light concentrating mirror 15 to the intermediate focal point IF is 2.1 m and it is desired that the attenuation rate of the EUV light 101 is 10% or less, the pressure in the second space S2 is, for example, 30 Pa or lower, and the pressure in the first space S1 is, for example, 100 Pa or higher.

The processor 120 waits until a predetermined time elapses after starting the introduction of the etching gas into the first space S1 and the second space S2 and forming the gas curtain GC by the gas curtain forming device 5. Thereafter, similarly to the comparative example, the processor 120 causes the droplet target DL to be irradiated with the laser light 90 in the plasma generation region AR, and the light including the EUV light 101 is output from the plasma generation region AR.

A part of the light including the EUV light 101 generated in the plasma generation region AR passes through the first opening 21 and is transmitted through the gas curtain GC. The EUV light 101 transmitted through the gas curtain GC travels to the EUV light concentrating mirror 15, is concentrated by the EUV light concentrating mirror 15 at the intermediate focal point IF, and then enters the exposure apparatus 200 from the connection portion 9.

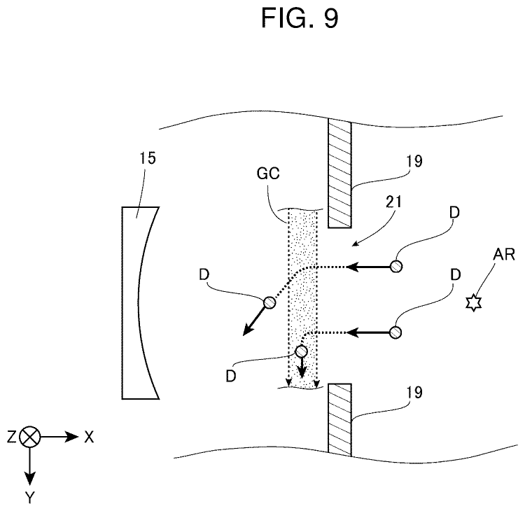

Further, in the plasma generation region AR, debris is scattered from the droplet target DL by being irradiated with the laser light 90. FIG. 9 is a schematic view showing the movement of debris D. FIG. 9 is an enlarged view of the vicinity of the gas curtain GC. In FIG. 9, the gas injection unit 400 and the gas collection unit 500 are omitted. Further, FIG. 9 shows the velocity of the debris D by arrows, and the movement path of the debris D by broken lines. As shown in FIG. 9, a part of the debris D generated in the plasma generation region AR is scattered toward the first opening 21. The debris D scattered toward the first opening 21 is flowed by the flow of hydrogen molecules in the gas curtain GC. A part of the debris D scattered toward the first opening 21 collides with the hydrogen molecules in the gas curtain GC, loses the kinetic energy in the direction from the plasma generation region AR toward the EUV light concentrating mirror 15, and obtains the kinetic energy in the direction in which the gas of the gas curtain GC flows. Therefore, the debris D is eliminated along the flow of the gas. Further, another part of the debris D loses a part of the kinetic energy in the direction from the plasma generation region AR toward the EUV light concentrating mirror 15 due to the collision with the hydrogen molecules, thereby obtaining the kinetic energy in the direction in which the gas flows. Therefore, the trajectory of the debris D is changed by the gas curtain GC, and the debris D enters the second space S2 from the first opening 21 but hardly adheres to the EUV light concentrating mirror 15.

### 4.3 Effect

In the EUV light generation chamber device 150, the pressure in the second space S2 is lower than the pressure in the first space S1. Therefore, the EUV light generation chamber device 150 can suppress the EUV light 101 from being absorbed by the etching gas due to a decrease in the density of the etching gas in the second space S2.

Further, the EUV light generation chamber device 150 causes a part of the debris D generated from the droplet target DL in the plasma generation region AR to collide with the molecules of the gas contained in the gas curtain GC. Therefore, the EUV light generation chamber device 150 may discharge the debris D together with the gas, and may suppress the debris D from entering the second space S2. Further, the EUV light generation chamber device 150 can change the travel direction of the debris D from the direction toward the EUV light concentrating mirror 15 to another direction by the gas curtain GC. Therefore, the EUV light generation chamber device 150 can suppress the debris D from adhering to the EUV light concentrating mirror 15.

Therefore, the EUV light generation chamber device 150 can suppress the debris D from adhering to the EUV light concentrating mirror 15 by the gas curtain GC even when the pressure of the etching gas in the second space S2 is low. Therefore, since the debris D can be suppressed from adhering to the EUV light concentrating mirror 15 without increasing the distance between the plasma generation region AR and the EUV light concentrating mirror 15, the EUV light generation chamber device 150 can be reduced in size.

In the EUV light generation chamber device 150, the pressure of the etching gas in the first space S1 is higher than the pressure of the etching gas in the second space S2. Therefore, the EUV light generation chamber device 150 can effectively eliminate scattered tin by causing the tin scattered in the first space S1 to react with the hydrogen contained in the etching gas.

As described above, the EUV light generation chamber device 150 of the present embodiment can suppress decrease of the power of the EUV light 101 and adhesion of the debris D to the EUV light concentrating mirror 15 while reducing the size thereof.

The EUV light generation chamber device 150 may not include the second partition wall 19. In this case, the EUV light concentrating mirror 15 side of the gas curtain GC may be the second space S2, and the plasma generation region AR side thereof may be the first space S1. However, it is preferable to provide the second partition wall 19 from the viewpoint of suppressing scattering of the debris D.

### 4.4 Description of First Modification

Next, a first modification of the EUV light generation chamber device 150 of the first embodiment will be described. Any component same as that described above is denoted by an identical reference sign, and duplicate description thereof is omitted unless specific description is needed.

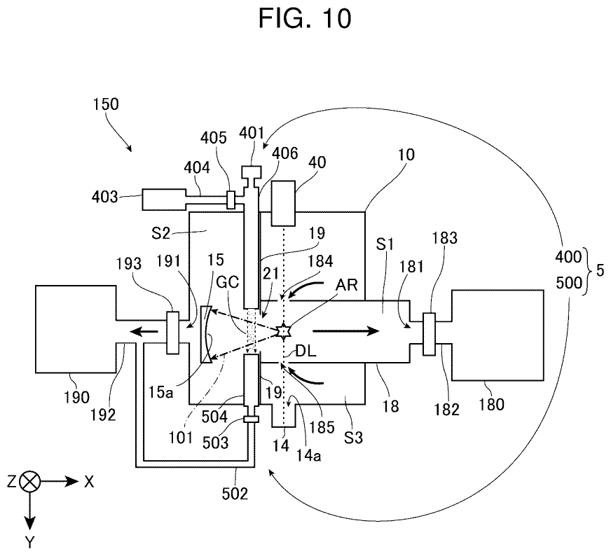

FIG. 10 is a schematic view of the EUV light generation chamber device 150 of the present modification shown in the same manner as FIG. 5. As shown in FIG. 10, the EUV light generation chamber device 150 of the present modification differs from the EUV light generation chamber device 150 of the first embodiment in that the second exhaust device 190 also serves as the fourth exhaust device 501. Therefore, in the present modification, the gas collection unit 500 does not include the fourth exhaust device 501. An end part of the pipe 502 located outside the chamber 10 is connected to the pipe 192 at a position between the second exhaust device 190 and the second valve 193. With this configuration, the second exhaust device 190 also serves as the fourth exhaust device 501.

According to the EUV light generation chamber device 150 of the present modification, the second exhaust device 190 exhausts the gas from the second space S2 and the second skimmer 504. Therefore, the EUV light generation chamber device 150 of the present modification can reduce the number of the exhaust devices.

### 4.5 Description of Second Modification

Next, a second modification of the EUV light generation chamber device 150 of the first embodiment will be described. Any component same as that described above is denoted by an identical reference sign, and duplicate description thereof is omitted unless specific description is needed.

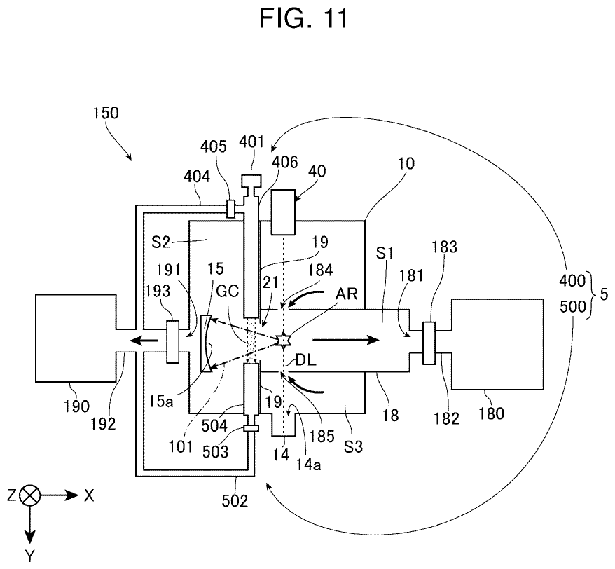

FIG. 11 is a schematic view of the EUV light generation chamber device 150 of the present modification shown in the same manner as FIG. 5. As shown in FIG. 11, the EUV light generation chamber device 150 of the present modification differs from the EUV light generation chamber device 150 of the first modification in that the second exhaust device 190 further serves as the third exhaust device 403. Therefore, in the present modification, the gas injection unit 400 does not include the third exhaust device 403. One end part of the pipe 404 is connected to the third gas exhaust port 408. The other end part of the pipe 404 is connected to the pipe 192 at a position between the second exhaust device 190 and the second valve 193. With this configuration, the second exhaust device 190 also serves as the third exhaust device 403.

According to the EUV light generation chamber device 150 of the present modification, the second exhaust device 190 exhausts the gas from the second space S2, the inside of the second skimmer 504, and the inside of the shroud 406. Therefore, the EUV light generation chamber device 150 of the present modification can reduce the number of the exhaust devices.

### 4.6 Description of Third Modification

Next, a third modification of the EUV light generation chamber device 150 of the first embodiment will be described. Any component same as that described above is denoted by an identical reference sign, and duplicate description thereof is omitted unless specific description is needed.

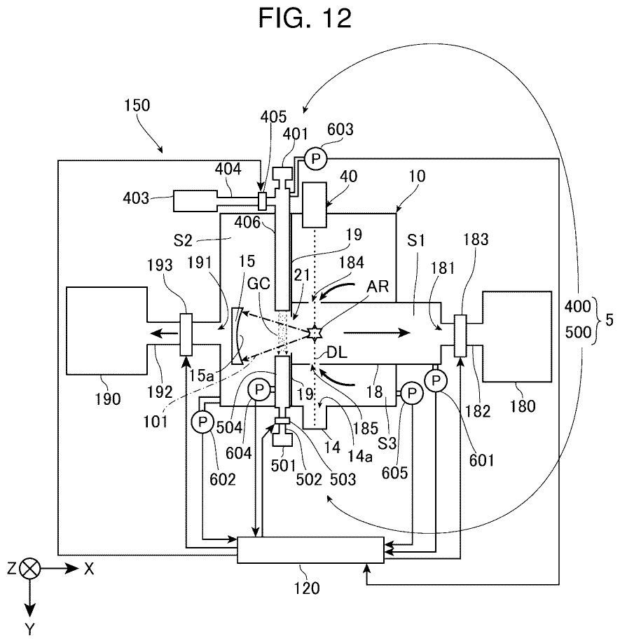

FIG. 12 is a schematic view of the EUV light generation chamber device 150 of the present modification shown in the same manner as FIG. 5. As shown in FIG. 12, the EUV light generation chamber device 150 of the present modification differs from the EUV light generation chamber device 150 of the first embodiment in including a first pressure sensor 601, a second pressure sensor 602, a third pressure sensor 603, a fourth pressure sensor 604, and a fifth pressure sensor 605. The first pressure sensor r 601, the second pressure sensor 602, the third pressure sensor 603, the fourth pressure sensor 604, and the fifth pressure sensor 605 are electrically connected to the processor 120 via a signal line or the like.

The first pressure sensor 601 measures the pressure in the first space S1 and outputs a signal indicating the measured pressure to the processor 120. The second pressure sensor 602 measures the pressure in the second space S2 and outputs a signal indicating the measured pressure to the processor 120. The third pressure sensor 603 measures the pressure in the shroud 406 and outputs a signal indicating the measured pressure to the processor 120. The fourth pressure sensor 604 measures the pressure in the second skimmer 504 and outputs a signal indicating the measured pressure to the processor 120. The fourth pressure sensor 604 may measure the pressure in the pipe 502. The fifth pressure sensor 605 measures the pressure in the third space S3 and outputs a signal indicating the measured pressure to the processor 120.

Further, the first valve 183, the second valve 193, the third valve 405, and the fourth valve 503 are electrically connected to the processor 120 via a signal line or the like. The opening degree of each of the first valve 183, the second valve 193, the third valve 405, and the fourth valve 503 is adjusted by the processor 120. The first valve 183, the second valve 193, the third valve 405, and the fourth valve 503 may each include a valve and a drive unit that controls the opening degree of the valve.

Next, operation of the processor 120 of the present modification will be described. The signals from the first pressure sensor 601, the second pressure sensor 602, the third pressure sensor 603, the fourth pressure sensor 604, and the fifth pressure sensor 605 are input to the processor 120. When the signals are input, the processor 120 controls the first valve 183, the second valve 193, the third valve 405, and the fourth valve 503 based on the input signals.

The processor 120 controls the first valve 183 and the second valve 193 so that the pressure in the second space S2 is lower than the pressure in the first space S1. At this time, the processor 120 may control the second valve 193 so that the pressure in the second space S2 becomes 30 Pa or lower, and may control the first valve 183 so that the pressure in the first space S1 becomes 100 Pa or higher.

Further, the processor 120 may also control the third valve 405 so that the pressure in the shroud 406 becomes approximately 10 Pa.

Further, the processor 120 may also control the fourth valve 503 so that the pressure in the second skimmer 504 is equal to or less than 30 Pa. Further, the processor 120 may also control the second valve 193 and the fourth valve 503 so that the pressure in the second skimmer 504 becomes lower than the pressure in the second space S2.

According to the EUV light generation chamber device 150 of the present modification, the processor 120 can control the pressure in the first space S1, the second space S2, the shroud 406, and the second skimmer 504. Therefore, since the EUV light generation chamber device 150 of the present modification can autonomously control the pressure in the first space S1, the second space S2, the shroud 406, and the second skimmer 504, it is easy to maintain the pressure distribution even against unexpected disturbance.

### 5. Description of Extreme Ultraviolet Light Generation Chamber Device of Second Embodiment

Next, the configuration of the EUV light generation chamber device 150 of a second embodiment will be described. Any component same as that described above is denoted by an identical reference sign, and duplicate description thereof is omitted unless specific description is needed.

### 5.1 Configuration

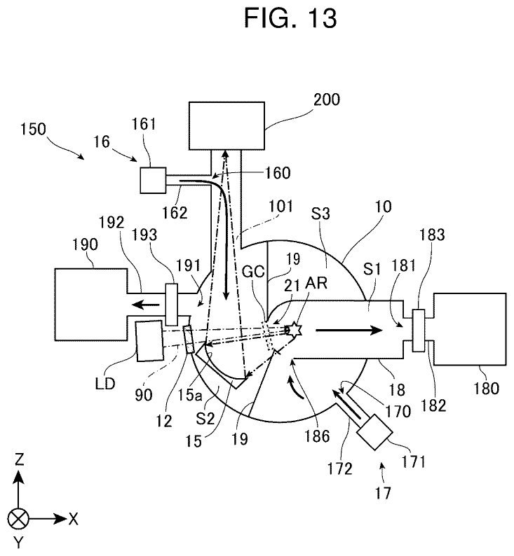

FIG. 13 is a schematic view of the EUV light generation chamber device 150 of the present embodiment shown in the same manner as FIG. 4. As shown in FIG. 13, the EUV light generation chamber device 150 of the present embodiment differs from the EUV light generation chamber device 150 of the first embodiment in that the window 12 through which the laser light 90 from the laser device LD is transmitted is arranged on the second space S2 side. In FIG. 13, to avoid complication of the drawing, dashed-dotted lines indicating the EUV light 101 propagating from the plasma generation region AR to the EUV light concentrating mirror 15 are slightly shifted.

The chamber 10 is provided with at least one through hole communicating with the second space S2, and the through hole is closed by the window 12. The window 12 is provided in a wall of the chamber 10 on the second space S2 side.

In the present embodiment, the laser light 90 from the laser device LD enters the chamber 10 through the window 12, and is radiated to the plasma generation region AR through the gas curtain GC and the first opening 21.

### 5.2 Effect

In the present embodiment, in the EUV light generation chamber device 150, the window 12 is provided at the chamber 10 on the second space S2 side. As described above, the EUV light generation chamber device 150 can suppress the debris D from entering the second space S2 due to the gas curtain GC. Therefore, the EUV light generation chamber device 150 of the present embodiment can suppress the debris D from adhering to the inner surface of the window 12 provided on the second space S2 side.

Further, the EUV light generation chamber device 150 of the present embodiment can reduce the amount of the etching gas flowing in the third space S3 to suppress adhesion of the debris D to the window 12 provided on the third space S3 side, and can reduce the pressure in the first space S1, as compared with the case in which the window 12 is provided on the third space S3 side. Therefore, the EUV light generation chamber device 150 can suppress the EUV light 101 from being absorbed by the hydrogen on the optical path from the plasma generation region AR to the gas curtain GC.

In the present embodiment, the second opening 186 may not be provided in the first partition wall 18.

Further, in the first, second, and third modifications, the window 12 may be provided on the second space S2 side as in the second embodiment.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that embodiments of the present disclosure would be appropriately combined. The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and c.

What is claimed is:

1. An extreme ultraviolet light generation chamber device comprising:
a chamber including, at an internal space thereof, a plasma generation region in which a droplet target irradiated with laser light is turned into plasma and extreme ultraviolet light is generated;
a light concentrating mirror arranged in the chamber and configured to concentrate the extreme ultraviolet light;
a gas curtain forming device configured to inject a gas at supersonic velocity and form a gas curtain that intersects an optical path of the extreme ultraviolet light propagating from the plasma generation region to the light concentrating mirror;
an etching gas supply unit configured to supply an etching gas into the chamber; and
a gas exhaust unit configured to exhaust a residual gas in the chamber,
in the chamber, pressure in a second space that is a space on a side toward the light concentrating mirror from the gas curtain being lower than pressure in a first space that is a space on a side toward the plasma generation region from the gas curtain and that includes the plasma generation region.

2. The extreme ultraviolet light generation chamber device according to claim 1,
wherein the gas contains hydrogen.

3. The extreme ultraviolet: generation chamber device according to claim 2,
wherein the droplet target contains tin.

4. The extreme ultraviolet light generation chamber device according to claim 1,
further comprising a cylindrical first partition wall that surrounds the first space and that is provided with a first opening through which the extreme ultraviolet light propagating from the plasma generation region to the light concentrating mirror passes and which communicates with the second space,
wherein the gas curtain covers at least a part of the first opening.

5. The extreme ultraviolet light generation chamber device according to claim 4,
further comprising a second partition wall that isolates a third space being a space outside the first partition wall and the second space and is connected to the first partition wall.

6. The extreme ultraviolet light generation chamber device according to claim 1,
wherein the etching gas supply unit includes a first etching gas supply unit configured to supply the etching gas to the first space and a second etching gas supply unit configured to supply the etching gas to the second space, and
the gas exhaust unit includes a first exhaust device configured to exhaust the residual gas from the first space and a second exhaust device configured to exhaust the residual gas from the second space.

7. The extreme ultraviolet light generation chamber device according to claim 6, further comprising:
a first pressure sensor configured to measure pressure in the first space;
a second pressure sensor configured to measure pressure in the second space; and
a processor,
wherein the gas exhaust unit includes a first valve arranged at a pipe connecting the first space and the first exhaust device, and a second valve arranged at a pipe connecting the second space and the second exhaust device,
a signal indicating the pressure measured by the first pressure sensor and a signal indicating the pressure measured by the second pressure sensor are input to the processor, and
the processor controls the first valve and the second valve so that the pressure in the second space becomes lower than the pressure in the first space.

8. The extreme ultraviolet light generation chamber device according to claim 1,
wherein the gas curtain forming device includes a gas injection unit configured to inject the gas, and a gas collection unit configured to collect the gas,
the gas injection unit includes a gas supply unit configured to supply the gas, a Laval nozzle through which the gas supplied from the gas supply unit passes, a shroud including the Laval nozzle at an internal space thereof, a first skimmer arranged at the shroud such that a cross-sectional area thereof becomes large toward a direction in which the gas is injected, and a third exhaust device configured to exhaust from the shroud the gas that is not injected from the first skimmer, and
the gas collection unit includes a second skimmer arranged at a position proceeding in the direction in which the gas is injected from the first skimmer such that a cross-sectional area thereof becomes large toward the direction in which the gas is injected, and a fourth exhaust device configured to exhaust the gas having flowed into the second skimmer.

9. The extreme ultraviolet light generation chamber device according to claim 8,
wherein the etching gas supply unit includes a first etching gas supply unit configured to supply the etching gas to the first space and a second etching gas supply unit configured to supply the etching gas to the second space, and
the gas exhaust unit includes a first exhaust device configured to exhaust the residual gas from the first space and a second exhaust device configured to exhaust the residual gas from the second space.

10. The extreme ultraviolet light generation chamber device according to claim 9,
wherein the second exhaust device also serves as the fourth exhaust device.

11. The extreme ultraviolet light generation chamber device according to claim 10,
wherein the second exhaust device further serves as the third exhaust device.

12. The extreme ultraviolet light generation chamber device according to claim 9, further comprising:
a first pressure sensor configured to measure pressure in the first space;
a second pressure sensor configured to measure pressure in the second space; and
a processor,
wherein the gas exhaust unit includes a first valve arranged at a pipe connecting the first space and the first exhaust device, and a second valve arranged at a pipe connecting the second space and the second exhaust device,
a signal indicating the pressure measured by the first pressure sensor and a signal indicating the pressure measured by the second pressure sensor are input to the processor, and
the processor controls the first valve and the second valve so that the pressure in the second space becomes lower than the pressure in the first space.

13. The extreme ultraviolet light generation chamber device according to claim 12,
further comprising a fourth pressure sensor configured to measure pressure at an internal space of the second skimmer,
wherein the gas collection unit includes a fourth valve arranged at a pipe connecting the internal space of the second skimmer and the fourth exhaust device,
a signal indicating the pressure measured by the fourth pressure sensor is input to the processor, and
the processor controls the fourth valve so that the pressure at the internal space of the second skimmer becomes lower than the pressure in the second space.

14. The extreme ultraviolet light generation chamber device according to claim 1,
further comprising a window which is arranged in a wall of the chamber on a side toward the second space and through which the laser light is transmitted,
wherein the plasma generation region is irradiated with the laser light through the window.

15. An electronic device manufacturing method, comprising:
outputting extreme ultraviolet light generated using an extreme ultraviolet light generation apparatus including an extreme ultraviolet light generation chamber device to an exposure apparatus; and
exposing a photosensitive substrate to the extreme ultraviolet light in the exposure apparatus to manufacture an electronic device,
the extreme ultraviolet light generation chamber device including:
a chamber including, at an internal space thereof, a plasma generation region in which a droplet target irradiated with laser light is turned into plasma and the extreme ultraviolet light is generated;
a light concentrating mirror arranged in the chamber and configured to concentrate the extreme ultraviolet light;
a gas curtain forming device configured to inject a gas at supersonic velocity and form a gas curtain that intersects an optical path of the extreme ultraviolet light propagating from the plasma generation region to the light concentrating mirror;
an etching gas supply unit configured to supply an etching gas into the chamber; and
a gas exhaust device configured to exhaust a residual gas in the chamber,
in the chamber, pressure in a second space that is a space on a side toward the light concentrating mirror from the gas curtain being lower than pressure in a first space that is a space on a side to the plasma generation region from the gas curtain and that includes the plasma generation region.

16. An electronic device manufacturing method, comprising:
inspecting a defect of a mask by irradiating the mask with extreme ultraviolet light generated using an extreme ultraviolet light generation apparatus including an extreme ultraviolet light generation chamber device;
selecting a mask using a result of the inspection; and
exposing and transferring a pattern formed on the selected mask onto a photosensitive substrate,
the extreme ultraviolet light generation chamber device including:
a chamber including, at an internal space thereof, a plasma generation region in which a droplet target irradiated with laser light is turned into plasma and the extreme ultraviolet light is generated;
a light concentrating mirror arranged in the chamber and configured to concentrate the extreme ultraviolet light;
a gas curtain forming device configured to inject a gas at supersonic velocity and form a gas curtain that intersects an optical path of the extreme ultraviolet light propagating from the plasma generation region to the light concentrating mirror;
an etching gas supply unit configured to supply an etching gas into the chamber; and
a gas exhaust device configured to exhaust a residual gas in the chamber;
in the chamber, pressure in a second space that is a space on a side toward the light concentrating mirror from the gas curtain being lower than pressure in a first space that is a space on a side toward the plasma generation region from the gas curtain and that includes the plasma generation region.
